(19) United States
(12) Patent Application Publication
(10) Pub. No.: US 2026/0344440 A1
(43) Pub. Date: Oct. 29, 2026

(54) INTEGRATED CIRCUIT PACKAGES AND METHODS OF FORMING THE SAME

(71) Applicant: Taiwan Semiconductor Manufacturing Co., Ltd., Hsinchu (TW)

(72) Inventors: Wen-Yi Lin, New Taipei City (TW); Chien-Li Kuo, Hsinchu (TW); Kuang-Chun Lee, New Taipei City (TW); Chien-Chen Li, Hsinchu (TW); Kuo-Chio Liu, Hsinchu (TW)

(21) Appl. No.: 19/727,026

(22) Filed: Jul. 1, 2026

Related U.S. Application Data
(62) Division of application No. 17/898,075, filed on Aug. 29, 2022.

(51) Int. Cl. H10W 42/00; H10W 74/01; H10W 74/15; H10W 76/01; H10W 90/00

(52) U.S. Cl. CPC H10W 42/121; H10W 74/012; H10W 74/15; H10W 76/01; H10W 90/701; H10W 90/721; H10W 90/734

(57) ABSTRACT

Integrated circuit packages and methods of forming the same are discussed. In an embodiment, a device includes: a package substrate; a semiconductor device attached to the package substrate; an underfill between the semiconductor device and the package substrate; and a package stiffener attached to the package substrate, the package stiffener includes: a main body extending around the semiconductor device and the underfill in a top-down view, the main body having a first coefficient of thermal expansion; and pillars in the main body, each of the pillars extending from a top surface of the main body to a bottom surface of the main body, each of the pillars physically contacting the main body, the pillars having a second coefficient of thermal expansion, the second coefficient of thermal expansion being less than the first coefficient of thermal expansion.

### PRIORITY CLAIM AND CROSS-REFERENCE

This application is a divisional of U.S. patent application Ser. No. 17/898,075, filed on Aug. 29, 2022, which application is hereby incorporated herein by reference.

### BACKGROUND

The semiconductor industry has experienced rapid growth due to ongoing improvements in the integration density of a variety of electronic components (e.g., transistors, diodes, resistors, capacitors, etc.). For the most part, improvement in integration density has resulted from iterative reduction of minimum feature size, which allows more components to be integrated into a given area. As the demand for shrinking electronic devices has grown, a need for smaller and more creative packaging techniques of semiconductor dies has emerged.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIGS. 1A-9B are views of intermediate steps during a process for forming an integrated circuit package, in accordance with some embodiments.

FIGS. 10A-10E are top-down views of package stiffeners, in accordance with some embodiments.

FIGS. 11A-14B are views of intermediate steps during a process for forming an integrated circuit package, in accordance with some embodiments.

FIGS. 15A-15B are views of an integrated circuit package, in accordance with some embodiments.

FIGS. 16A-16B are views of an integrated circuit package, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In accordance with some embodiments, a package stiffener for an integrated circuit package includes a main body and pillars disposed in the main body. The package stiffener serves to provide structural stability and reduce warpage across a package substrate of the integrated circuit package. Testing or operation of the integrated circuit package may induce warpage due to differences in coefficients of thermal expansion between the package stiffener and the package substrate. The pillars are formed of a different material than the main body of the package stiffener, and the materials of the package stiffener are selected to help reduce a mismatch in the coefficients of thermal expansion of the package stiffener and the package substrate. Device warpage may thus be reduced, which may increase the reliability of the integrated circuit package.

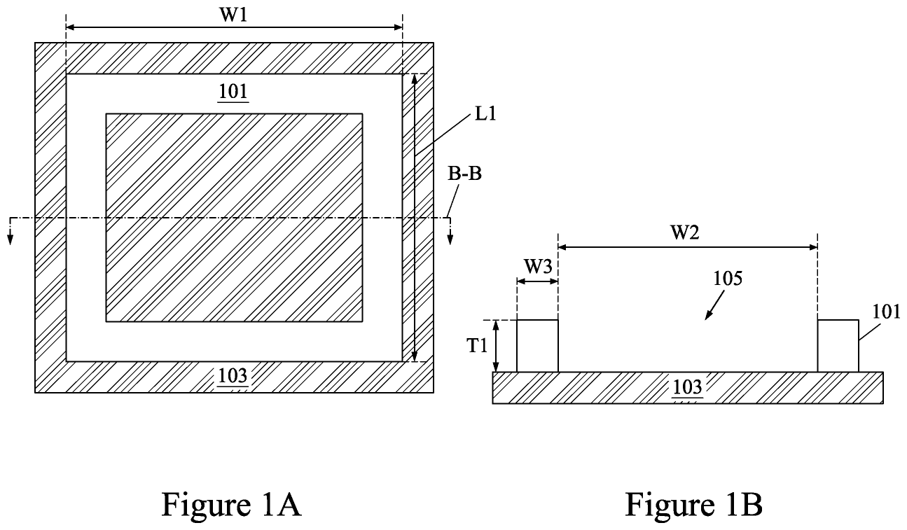

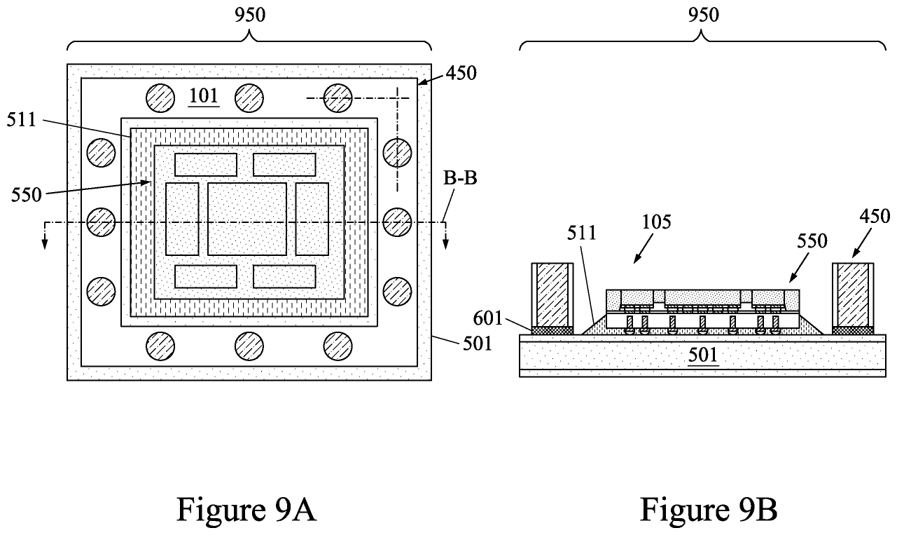

FIGS. 1A-9B are views of intermediate steps during a process for forming an integrated circuit package 950, in accordance with some embodiments. FIGS. 1A, 2A, 3A, 4A, 5A, 6A, 7A, 8A, and 9A are top-down views. FIGS. 1B, 2B, 3B, 4B, 5B, 6B, 7B, 8B, and 9B are cross-sectional views shown along cross-section B-B in, respectively, FIGS. 1A, 2A, 3A, 4A, 5A, 6A, 7A, 8A, and 9A. In some embodiments, the integrated circuit package 950 (see FIGS. 9A-9B) is a chip-on-wafer-on substrate (CoWoS) package. It should be appreciated that the integrated circuit package 950 may be another type of package.

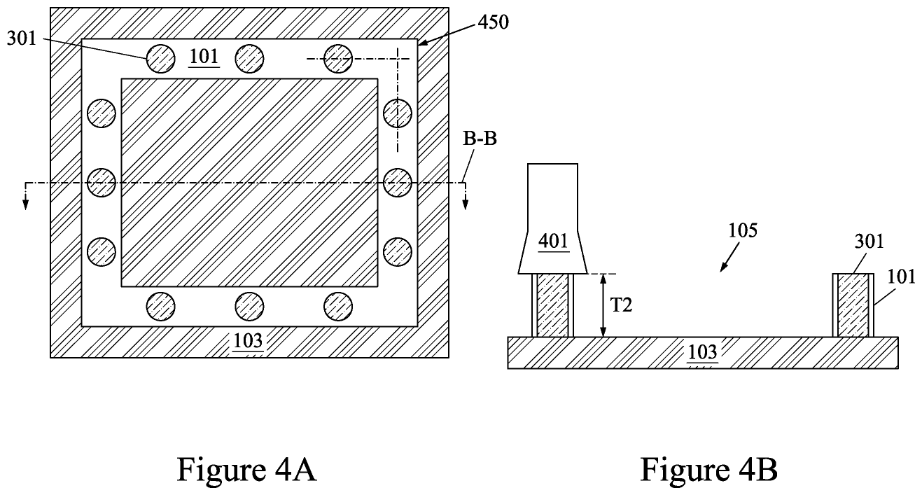

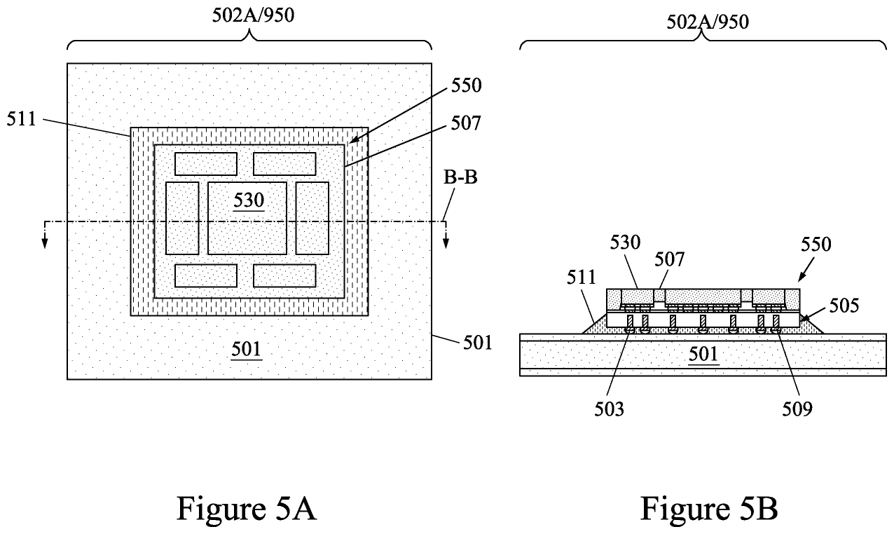

The integrated circuit package 950 is formed by initially forming a package stiffener 450 (see FIGS. 4A-4B) and then subsequently attaching the package stiffener 450 and a semiconductor device 550 (see FIGS. 5A-5B) to a package substrate 501 (see FIGS. 9A-9B). The package stiffener 450 includes multiple materials, which are selected to reduce a coefficient of thermal expansion (CTE) mismatch between the package stiffener 450 and the package substrate 501.

In FIGS. 1A-1B, a stiffener main body 101 is placed on a processing substrate 103. The processing substrate 103 is any substrate or workpiece that may provide mechanical support to facilitate subsequent processing steps to form the package stiffener. The processing substrate 103 may be a mounting plate, although any other appropriate manufacturing apparatuses may be utilized.

In this embodiment, the stiffener main body 101 is a metal ring having an opening 105 extending through the middle of the metal ring. Thus, the stiffener main body 101 has a ring shaped profile in the top-down view. The opening 105 provides an area for a semiconductor device to be subsequently disposed in. In this embodiment, the metal ring is a rectangular metal ring. The rectangular metal ring is defined by straight horizontal and vertical portions of the stiffener main body 101 in the top-down view. In some embodiments where the stiffener main body 101 is a rectangular metal ring, the stiffener main body 101 may have an outer width W1 of about 70 mm, such as in the range of 50 mm to 110 mm; the stiffener main body 101 may have an outer length L1 of about 70 mm, such as in the range of 50 mm to 110 mm; the stiffener main body 101 may have an inner width W2 (e.g., of the opening 105) in the range of 30 mm to 90 mm; the horizontal/vertical portions of the stiffener main body 101 may have a width W3 of about 5 mm, such as in the range of 3 mm to 8 mm; and the stiffener main body 101 may have a thickness T1 of about 3 mm, such as in the range of 1 mm to 5 mm. It should be appreciated that the rectangular metal ring as depicted in FIG. 1A is merely illustrative of one embodiment and any appropriate geometry for the stiffener main body 101 may be utilized.

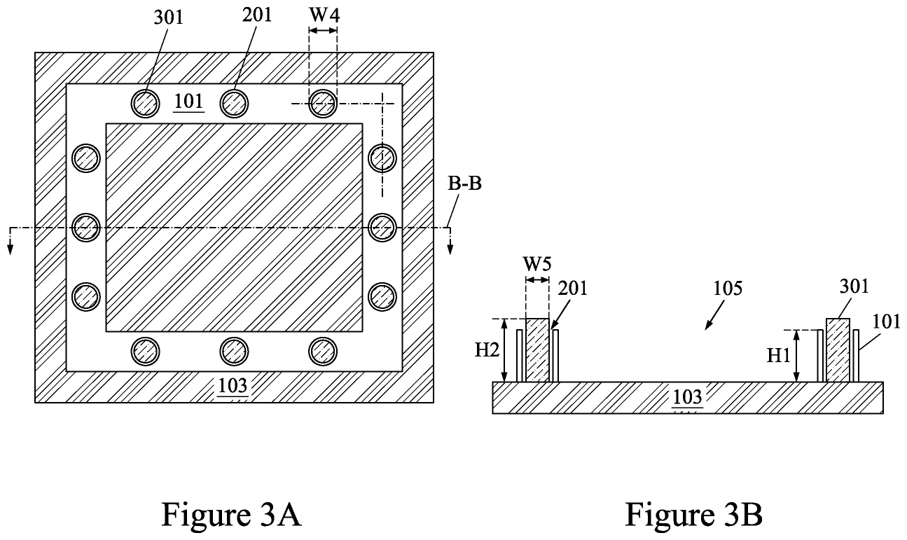

The stiffener main body 101 is formed of a rigid material that will remain substantially undeformed during subsequent processing. Specifically, the rigid material of the stiffener main body 101 has a large Young's modulus, a large Poisson's ratio, and a large density. In some embodiments, the stiffener main body 101 is formed of a metal. For example, the stiffener main body 101 may comprise copper. As another example, the stiffener main body 101 may comprise an iron-nickel alloy, which comprises from 55% to 65% iron and from 35% to 45% nickel, such as Alloy 42. As yet another example, the stiffener main body 101 may comprise an iron-chromium alloy, which comprises from 82% to 86% iron and from 14% to 18% chromium, such as Stainless Steel 430. The stiffener main body 101 may have a Young's modulus of at least 100 GPa, such as about 118 GPa, such as in the range of 105 GPa to 130 GPa. The stiffener main body 101 may have a Poisson's ratio of at least 0.2, such as about 0.34, such as in the range of 0.3 to 0.4. The stiffener main body 101 may have a density of at least 2 g/cc, such as in the range of 2.5 g/cc to 9 g/cc. When the stiffener main body 101 is formed of a metal, it may have a low electrical resistivity, a high melting point, and a high thermal conductivity. The stiffener main body 101 may have an electrical resistivity of about 1.68×10⁻⁸ ohm-m. The stiffener main body 101 may have a melting point of at least 260 °C. The stiffener main body 101 may have a thermal conductivity of at least 10 W/mK. The stiffener main body 101 may be formed by an appropriate manufacturing process, such as a stamping press process, a machining process, or the like. The rigid material of the stiffener main body 101 has a large coefficient of thermal expansion, The stiffener main body 101 may have a coefficient of thermal expansion of at least 3 ppm/°C, such as about 17 ppm/°C, such as in the range of 12 ppm/°C to 23 ppm/°C. As subsequently described in greater detail, stiffener pillars 301 (see FIGS. 3A-3B) will be inserted into the stiffener main body 101 to help reduce the coefficient of thermal expansion of the resulting stiffener ring.

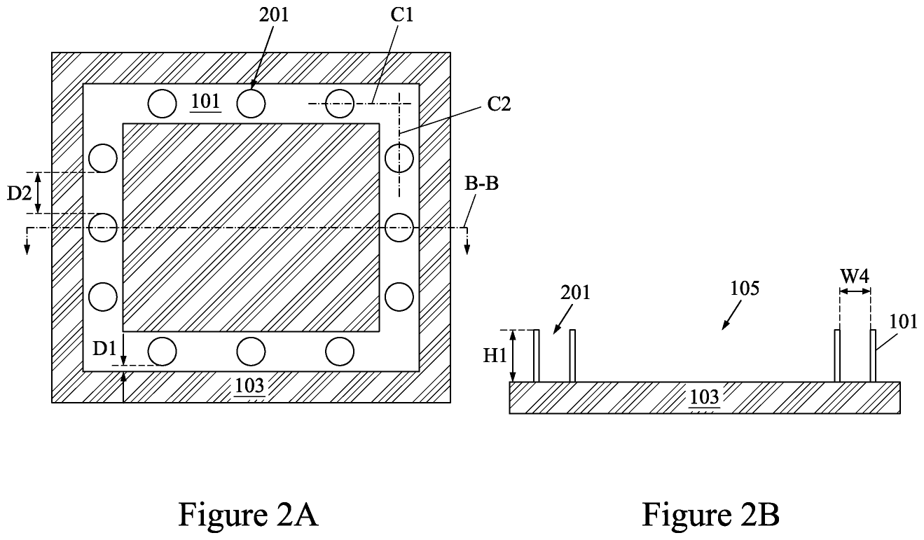

In FIGS. 2A-2B, stiffener holes 201 for stiffener pillars are patterned in the stiffener main body 101. The stiffener holes 201 extend entirely through the stiffener main body 101. Any suitable manufacturing process may be utilized to pattern the stiffener holes 201. In some embodiments, the stiffener holes 201 may be patterned by a drilling process that utilizes appropriate mechanical or laser drilling procedures to drill the stiffener holes 201 into the stiffener main body 101.

The stiffener holes 201 are oriented along the various portions (e.g., the horizontal portions and vertical portions) of the stiffener main body 101 in the top-down view. The stiffener holes 201 positioned along the horizontal portions are oriented along the corresponding centerlines of the horizontal portions (e.g. centerline C1). The stiffener holes 201 positioned along the vertical portions are oriented along the corresponding centerlines of the vertical portions (e.g. centerline C2). As such, each stiffener hole 201 is disposed a same distance D1 from an inner sidewall and an outer sidewall of the respective portion of the stiffener main body 101. The distance D1 may be in the range of 0.5 mm to 3 mm. The stiffener holes 201 may each have a width W4 in the range of 2 mm to 5 mm. The stiffener holes 201 have a height H1 that is equal to the initial thickness T1. The stiffener holes 201 are separated from one another by a distance D2. The distance D2 is at least 100 μm, such as in the range of 500 μm to 10000 μm. In an embodiment, the CTE depends in part on the distance D2.

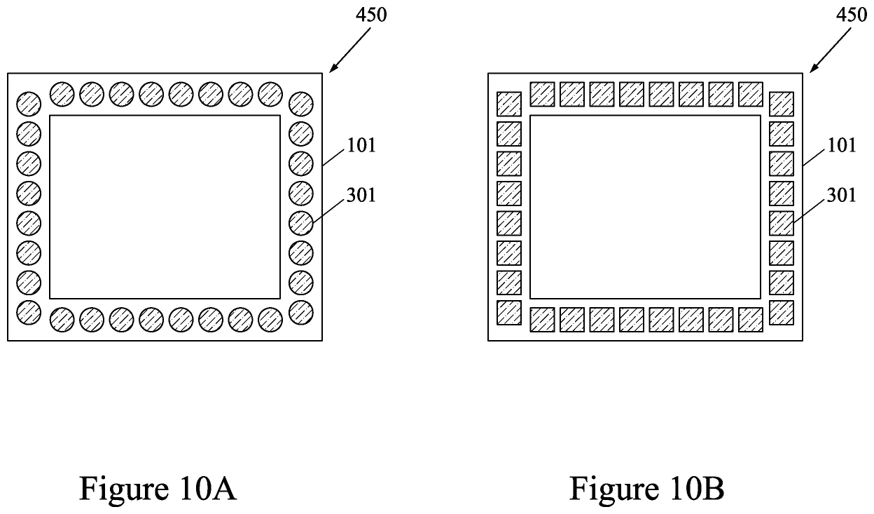

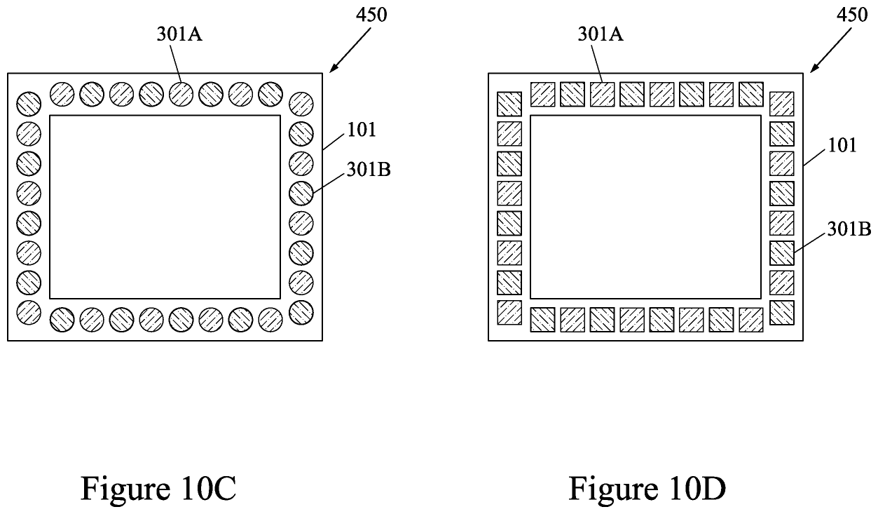

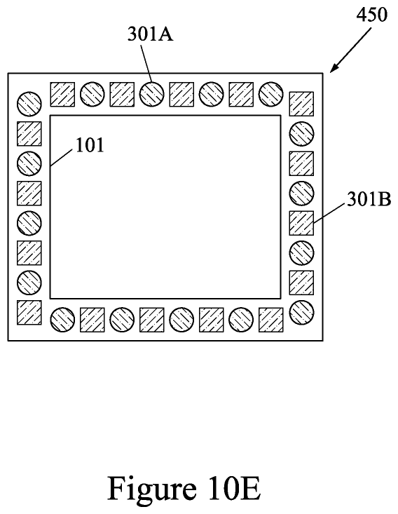

In this embodiment, the stiffener holes 201 are cylindrical holes. When the stiffener holes 201 are cylindrical holes, the width W4 is the diameter of the cylindrical holes. The cylindrical holes are circular in the top-down view. It should be appreciated that the cylindrical holes are merely one embodiment and other types of main body holes may be utilized as discussed in greater detail with respect to FIGS. 10A-10E.

In FIGS. 3A-3B, stiffener pillars 301 are placed in the stiffener holes 201. The stiffener pillars 301 have the same type of shape as the stiffener holes 201, but initially have different dimensions. Specifically, the stiffener pillars 301 have a width W5 that is less than the width W4 of the stiffener holes 201, and have a height H2 that is greater than the height H1 of the stiffener holes 201. The height H2 may be in the range of 0.1 mm to 5 mm and the width W5 may be in the range of 1.95 mm to 4.95 mm. In this embodiment where the stiffener holes 201 are cylindrical holes, the stiffener pillars 301 are cylindrical pillars, where the width W5 is the diameter of the cylindrical pillars. The cylindrical pillars are circular in the top-down view. Because the width W5 of the stiffener pillars 301 is less than the width W4 of the stiffener holes 201, the stiffener pillars 301 may be easily placed within the stiffener holes 201. After the stiffener pillars 301 are placed in the stiffener holes 201, they rest on a top surface of the processing substrate 103 such that difference in the height H2 and the height H1 results in the stiffener pillars 301 extending out of the stiffener holes 201 and above a top surface of the stiffener main body 101.

The stiffener pillars 301 are formed of a deformable material that is capable of being deformed during subsequent processing. Specifically, the deformable material of the stiffener pillars 301 has a larger Young's modulus and a smaller Poisson's ratio than the rigid material of the stiffener main body 101. In some embodiments, the stiffener pillars 301 are formed of a metal. For example, the stiffener pillars 301 may comprise an iron-nickel alloy, which comprises from 55% to 65% iron and from 35% to 45% nickel, such as Alloy 42. As yet another example, the stiffener pillars 301 may comprise an iron-chromium alloy, which comprises from 82% to 86% iron and from 14% to 18% chromium, such as Stainless Steel 430. In some embodiments, the stiffener main body 101 is formed of copper and the stiffener pillars 301 are formed of Alloy 42 or Stainless Steel 430. The stiffener pillars 301 may have a Young's modulus of at least 40 GPa, such as about 138 GPa, such as in the range of 60 GPa and 200 GPa. The stiffener pillars 301 may have a Poisson's ratio of at least 0.2, such as about 0.25, such as in the range of 0.22 to 0.28. The stiffener pillars 301 may have a density of at least 2 g/cc, such as in the range of 2.5 g/cc to 9 g/cc. When the stiffener pillars 301 are formed of a metal, it may have a low electrical resistivity, a high melting point, and a high thermal conductivity. The stiffener pillars 301 may have a melting point of at least 260 °C. The stiffener pillars 301 may have an electrical resistivity of about 7.1×10⁻⁷ ohm-m. The stiffener main body 101 have a different (e.g., smaller) electrical resistivity than the stiffener pillars 301. The stiffener pillars 301 may have a thermal conductivity of at least 10 W/mK. The stiffener pillars 301 may be formed by an appropriate manufacturing process, such as a stamping press process, a machining process, or the like. The deformable material of the stiffener pillars 301 has a smaller coefficient of thermal expansion than the rigid material of the stiffener main body 101. The stiffener pillars 301 may have a coefficient of thermal expansion of at least 3 ppm/°C, such as about 5.3 ppm/°C, such as in the range of 4 ppm/°C and 15 ppm/°C. Placing the stiffener pillars 301 in the stiffener main body 101 may help reduce the coefficient of thermal expansion of the resulting stiffener ring.

The stiffener pillars 301 are separated from each other, such that they are discontinuous. The stiffener pillars 301 may be separated from each other by the distance D2 (previously described). The stiffener main body 101 extends continuously around the stiffener pillars 301 in the top-down view.

In FIGS. 4A-4B, the stiffener pillars 301 are deformed so that they are secured into each of the stiffener holes 201, thereby forming the package stiffener 450. The stiffener pillars 301 may be deformed by a stamping press process or the like. The stamping press process includes pressing the stiffener pillars 301 into the stiffener holes 201 and against the processing substrate 103 with sufficient force to deform the stiffener pillars 301 so that the stiffener pillars 301 are compressed vertically and expand laterally to fill the stiffener holes 201. A relationship between the vertical compression of the stiffener pillars 301 to the lateral expansion of the stiffener pillars is characterized by the Poisson's ratio of the material of the stiffener pillars 301. The Poisson's ratio is defined as

$$υ = \vert \frac{{ε}_{2}}{{ε}_{1}} \vert ,$$

where ν is Poisson's ratio, ε₁ is longitudinal strain, and ε₂ is transverse strain. The longitudinal strain ε₁ is defined as

$$\frac{Δ L}{L} or - \frac{Δ L}{L} ,$$

where L is the compressed vertical height. The transverse strain ε₂ is defined as

$$\frac{Δ W}{W} or - \frac{Δ W}{W} ,$$

where W is the non-expanded lateral width.

In some embodiments, a stamp 401 may be utilized to press the stiffener pillars 301 into the stiffener holes 201 and against the processing substrate 103. Following their deformation, the stiffener pillars 301 have a thickness T2, the thickness T2 being equal to the thickness T1 (see FIGS. 1A-1B). The thickness T2 may be less than about 10 mm, such as in the range of 1 mm to 5 mm. Further, the stiffener pillars 301 may have a diameter of about 3 mm, such as in the range of 1.95 mm to 4.95 mm, such that the maximum diameter is 30% less than the width W3 of horizontal/vertical portions of the stiffener main body 101 (see FIG. 1A). To facilitate subsequent processing steps in forming the integrated circuit package 950, the package stiffener 450 is then removed from the processing substrate 103.

Deforming (specifically, laterally expanding) the stiffener pillars 301 causes them to have a close fit with the stiffener holes 201. The stiffener pillars 301 physically contact the sidewalls of the stiffener main body 101 that define the stiffener holes 201, with no other compounds (e.g., adhesive) disposed between the stiffener pillars 301 and the stiffener main body 101. Following their deformation, the stiffener pillars 301 have a close fit characterized by having a small flatness (e.g., planarity of the top surface of the stiffener main body 101 with the top surfaces of the stiffener pillars 301) and a small parallelism (e.g., planarity of the sidewalls of the stiffener holes 201 with the sidewalls of the stiffener pillars 301). In some embodiments, the stiffener pillars 301 have a flatness with the stiffener main body 101 of about 0.15 mm, such as in the range of 0.05 mm to 0.15 mm, and have a parallelism with the stiffener holes 201 of about 0.15 mm, such as in the range of 0.05 mm to 0.15 mm. Such a flatness and parallelism may indicate the stiffener pillars 301 have a sufficiently close fit with the stiffener main body 101. The stiffener main body 101 may be substantially undeformed (within process variation) by the deforming of the stiffener pillars 301. For example, the stiffener main body 101 may not deform transversely by more than about 0.05 mm, and may not deform more than the stiffener pillars 301. As such, the stiffener main body 101 has substantially the same dimensions before and after deforming of the stiffener pillars 301. Securing the stiffener pillars 301 to the stiffener main body 101 by deforming them allows the stiffener pillars 301 to be secured without using an adhesive, which may improve device reliability and/or lower manufacturing costs.

As a result of placing the stiffener pillars 301 in the stiffener main body 101, the package stiffener 450 has an equivalent coefficient of thermal expansion that is less than the coefficient of thermal expansion of the stiffener main body 101. The package stiffener 450 may have an equivalent coefficient of thermal expansion of about 14.88 ppm/°C, such as equivalent coefficient of thermal expansion in the range of 14 ppm/°C to 15.6 ppm/°C. Similarly, the package stiffener 450 has an equivalent Young's modulus that is greater than the Young's modulus of the stiffener main body 101. The package stiffener 450 may have an equivalent Young's modulus of about 123.2 GPa, such as an equivalent Young's modulus in the range of 117 GPa to 129 GPa. The package stiffener 450 may have a melting point of at least 260 °C. The package stiffener 450 may have a density of at least 2 g/cc. The package stiffener 450 may have a thermal conductivity of at least 10 W/mK. Benefits of the package stiffener 450 include a reduced equivalent coefficient of thermal expansion compared to stiffener rings that do not include stiffener pillars.

FIGS. 5A-9B show further steps in the formation of the integrated circuit package 950. The integrated circuit package 950 is completed by attaching the package stiffener 450 and a semiconductor device 550 to a package substrate 501 (see FIGS. 9A-9B). A packaging region 502A is shown, in which the integrated circuit package 950 is formed. It should be appreciated that multiple packaging regions 502A can be simultaneously processed, and an integrated circuit package 950 can be formed in each of the packaging regions 502A (see FIGS. 5A-5B).

In FIGS. 5A-5B, a semiconductor device 550 is mounted to the package substrate 501. The semiconductor device 550 is mounted using conductive connectors 503. The semiconductor device 550 may be a bare integrated circuit die, or may be a package component that includes an integrated circuit die. In this embodiment, the semiconductor device 550 is a chip-on-wafer (CoW) package component that includes one or more integrated circuit dies 530 and an interposer 505. The integrated circuit dies 530 are attached to the interposer 505, which interconnects the integrated circuit dies 530. An encapsulant 507 may be formed over the interposer 505 and around the integrated circuit dies 530, thereby protecting the various components of the semiconductor device 550. The interposer 505 includes UBMs 509. The conductive connectors 503 connect the UBMs 509 to the package substrate 501. The semiconductor device 550 may be mounted to the package substrate 501 by placing the semiconductor device 550 on the package substrate 501 and reflowing the conductive connectors 503.

The package substrate 501 includes a substrate core (not separately illustrated) and bond pads (not separately illustrated) over the substrate core. The substrate core may be made of a semiconductor material such as silicon, germanium, diamond, or the like. Alternatively, compound materials such as silicon germanium, silicon carbide, gallium arsenic, indium arsenide, indium phosphide, silicon germanium carbide, gallium arsenic phosphide, gallium indium phosphide, combinations of these, and the like, may also be used. Additionally, the substrate core may be a SOI substrate. Generally, an SOI substrate includes a layer of a semiconductor material such as epitaxial silicon, germanium, silicon germanium, SOI, SGOI, or combinations thereof. The substrate core is, in one alternative embodiment, based on an insulating core such as a fiberglass reinforced resin core. One example core material is fiberglass resin such as FR4. Alternatives for the core material include bismaleimide-triazine BT resin, or alternatively, other PCB materials or films. Build up films such as ABF or other laminates may be used for the substrate core. In some embodiments, the package substrate 501 is an organic substrate, where the substrate core is formed of a combination of organic and inorganic materials.

The substrate core may include active and passive devices (not shown). A wide variety of devices such as transistors, capacitors, resistors, combinations of these, and the like may be used to generate the structural and functional requirements of the design for the device stack. The devices may be formed using any suitable methods.

The substrate core may also include metallization layers and vias (not shown), with the bond pads being physically and/or electrically coupled to the metallization layers and vias. The metallization layers may be formed over the active and passive devices and are designed to connect the various devices to form functional circuitry. The metallization layers may be formed of alternating layers of dielectric (e.g., low-k dielectric material) and conductive material (e.g., copper) with vias interconnecting the layers of conductive material and may be formed through any suitable process (such as deposition, damascene, dual damascene, or the like). In some embodiments, the substrate core is substantially free of active and passive devices.

In some embodiments, the conductive connectors 503 are reflowed to attach the semiconductor device 550 to the bond pads of the package substrate 501. The conductive connectors 503 electrically and/or physically couple the package substrate 501, including metallization layers in the substrate core, to the semiconductor device 550, including metallization layers in the interposer 505. In some embodiments, a solder resist (not separately illustrated) is formed on the substrate core. The conductive connectors 503 may be disposed in openings in the solder resist to be electrically and mechanically coupled to the bond pads. The solder resist may be used to protect areas of the package substrate 501 from external damage.

The conductive connectors 503 may have an epoxy flux (not shown) formed thereon before they are reflowed with at least some of the epoxy portion of the epoxy flux remaining after the semiconductor device 550 is attached to the package substrate 501. This remaining epoxy portion may act as an underfill to reduce stress and protect the joints resulting from the reflowing the conductive connectors 503. In some embodiments, an underfill 511 is formed between the semiconductor device 550 and the package substrate 501, surrounding the conductive connectors 503. The underfill 511 may be formed by a capillary flow process after the semiconductor device 550 is attached or may be formed by a suitable deposition method before the semiconductor device 550 is attached.

In some embodiments, passive devices (e.g., surface mount devices (SMDs), not shown) may also be attached to the semiconductor device 550 (e.g., to the UBMs 509) or to the package substrate 501 (e.g., to bond pads). For example, the passive devices may be bonded to a same surface of the semiconductor device 550 or the package substrate 501 as the conductive connectors 503. The passive devices may be attached to the semiconductor device 550 prior to mounting the semiconductor device 550 on the package substrate 501, or may be attached to the package substrate 501 or after mounting the semiconductor device 550 on the package substrate 501.

The package substrate 501 has a small equivalent coefficient of thermal expansion, particularly when the package substrate 501 is an organic substrate. In some embodiments the package substrate 501 has a coefficient of thermal expansion value of 14.5 ppm/°C. As subsequently described in greater detail, the equivalent coefficient of thermal expansion of the package substrate 501 will be better matched to the equivalent coefficient of thermal expansion of the package stiffener 450 (see FIGS. 4A-4B) than to other package stiffeners.

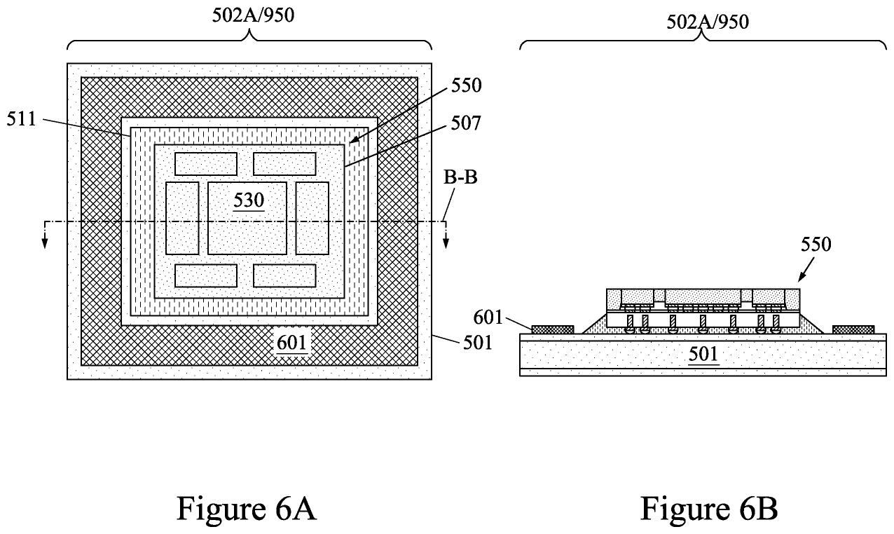

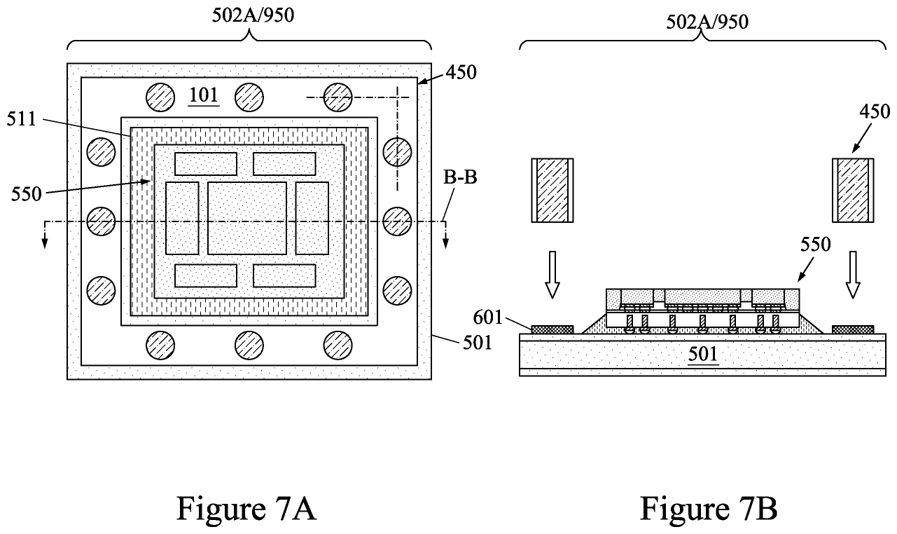

In FIGS. 6A-6B, an adhesive layer 601 is dispensed on an upper surface of the package substrate 501. The adhesive layer 601 may be any suitable non-conductive adhesive, epoxy, die attach film (DAF), or the like. The adhesive layer 601 is dispensed such that it provides an area where the package stiffener 450 (see FIGS. 7A-7B) will subsequently be adhered to the package substrate 501, and surrounds the semiconductor device 550. In another embodiment the adhesive layer 601 may be applied to a lower surface of the package stiffener 450 (not shown in FIGS. 6A-6B) before attaching the package stiffener 450 to the package substrate 501.

In FIGS. 7A-7B, the package stiffener 450 is aligned over the adhesive layer 601. The package stiffener 450 is aligned with the adhesive layer 601 such that the adhesive layer 601 may facilitate attaching the package stiffener 450 to the package substrate 501.

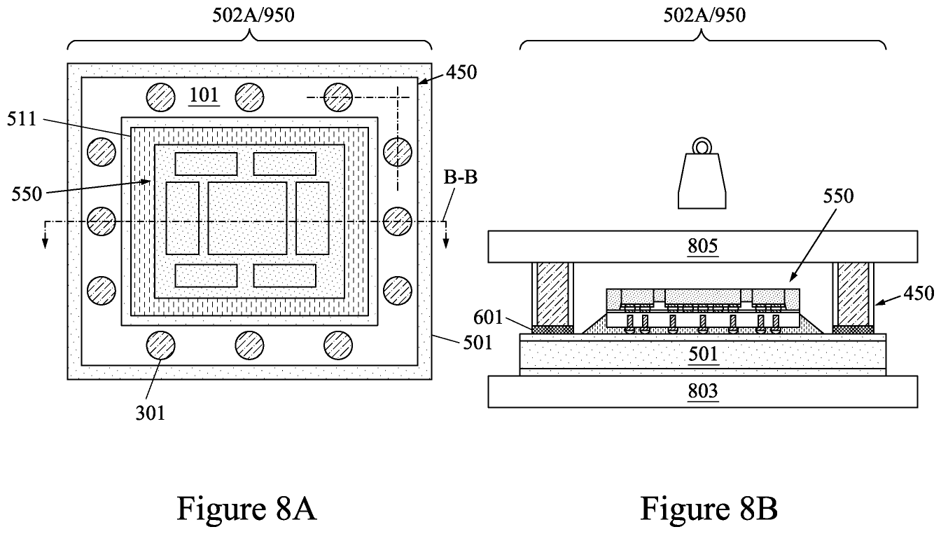

In FIGS. 8A-8B, the package stiffener 450 is adhered to the adhesive layer 601. Adhering the package stiffener 450 includes placing the package stiffener 450 on the adhesive layer 601 and performing an attachment process. In some embodiments the attachment process is a hot clamping process. The hot clamping process includes pressing the package stiffener 450 against the adhesive layer 601, and heating the adhesive layer 601. The package stiffener 450 may be pressed against the adhesive layer 601 by pressing a bottom processing plate 803 against the package substrate 501 and/or pressing a top processing plate 805 against the package stiffener 450 (not shown in FIG. 8A; see FIG. 8B). The package stiffener 450 may be pressed against the adhesive layer 601 with a force in the range of 100 N to 600 N. The adhesive layer 601 may be heated by applying heat to the bottom processing plate 803 and/or the top processing plate 805. The bottom processing plate 803 and/or the top processing plate 805 may be heated to a temperature in the range of 100 °C to 180 °C. The hot clamping process may occur for a duration in the range of 50 seconds to 200 seconds. The hot clamping process causes the adhesive layer to spread out as well as cure, and the result is the adhesion of the package stiffener 450 to the package substrate 501. The adhesive layer 601 physically contacts the bottom surfaces of the stiffener main body 101 and the stiffener pillars 301.

It should be appreciated that the process for attaching the package stiffener 450 to the package substrate 501 and the process for attaching the semiconductor device 550 to the package substrate 501 may be performed in either order. For example, the semiconductor device 550 may first be attached to the package substrate 501 and the package stiffener 450 may then be placed around the semiconductor device 550. Similarly, the package stiffener 450 may first be attached to the package substrate 501 and the semiconductor device 550 may then be placed in the opening 105 of the package stiffener 450.

In FIGS. 9A-9B, the integrated circuit package 950 is removed from the bottom processing plate 803 and the top processing plate 805 (see FIG. 8B). The resulting integrated circuit package 950 is illustrated. The package stiffener 450 fully encompasses the semiconductor device 550 in the top-down view.

As noted above, the package stiffener 450 has a decreased equivalent coefficient of thermal expansion as a result of including the stiffener pillars 301. Specifically, the package stiffener 450 has a smaller equivalent coefficient of thermal expansion than stiffener rings that do not include stiffener pillars (e.g., the stiffener main body 101 alone). Decreasing the equivalent coefficient of thermal expansion of the package stiffener 450 reduces a coefficient of thermal expansion mismatch between the package stiffener 450 and the package substrate 501. For example, the coefficient of thermal expansion mismatch between the package substrate 501 and the stiffener main body 101 may be in the range of 12 ppm/°C to 17 ppm/°C, and the coefficient of thermal expansion mismatch between the package substrate 501 and the package stiffener 450 may be in the range of 2 ppm/°C to 6 ppm/°C. The equivalent coefficient of thermal expansion of the package stiffener 450 is between the equivalent coefficient of thermal expansion of the package substrate 501 and the coefficient of thermal expansion of the stiffener main body 101. Warpage of the integrated circuit package 950 during testing or operation may thus be reduced, which may decrease the risk of the underfill 511 cracking. The reliability of the integrated circuit package 950 may thus be improved, particularly when the semiconductor device 550 has a large footprint (e.g., a footprint larger than 110 mm by 110 mm).

Other features and processes may also be included. For example, testing structures may be included to aid in the verification testing of the 3D packaging or 3DIC devices. The testing structures may include, for example, test pads formed in a redistribution layer or on a substrate that allows the testing of the 3D packaging or 3DIC, the use of probes and/or probe cards, and the like. The verification testing may be performed on intermediate structures as well as the final structure. Additionally, the structures and methods disclosed herein may be used in conjunction with testing methodologies that incorporate intermediate verification of known good dies to increase the yield and decrease costs.

FIG. 10A is a top-down view of a package stiffener 450, in accordance with some embodiments. In this embodiment, the number of stiffener pillars 301 is increased or decreased to control the desired coefficient of thermal expansion value of the resulting package stiffener 450. For example, the package stiffener 450 may include from 4 to 30 of the stiffener pillars 301.

FIG. 10B is a top-down view of a package stiffener 450, in accordance with some embodiments. This embodiment is similar to the embodiment of FIG. 10A, except the stiffener pillars 301 are square pillars. The square pillars are rectangular in the top-down view. While FIG. 10B illustrates the stiffener pillars 301 as square pillars, this is merely one embodiment and other appropriate geometries are intended to be included. The stiffener pillars 301 may have any appropriate geometry suited for manufacturing the package stiffener 450.

FIG. 10C is a top-down view of a package stiffener 450, in accordance with some embodiments. This embodiment is similar to the embodiment of FIG. 10A, except the stiffener pillars 301 include stiffener pillars formed of different materials. For example, a first subset of the stiffener pillars 301A are formed of a first material (e.g., Alloy 42) and a second subset of the stiffener pillars 301B are formed of a second material (e.g., Stainless Steel 430). The materials and quantities of the stiffener pillars 301A, 301B may be selected to achieve the desired coefficient of thermal expansion value of the resulting package stiffener 450.

FIG. 10D is a top-down view of a package stiffener 450, in accordance with some embodiments. This embodiment is similar to the embodiment of FIG. 10B, except the stiffener pillars 301 include stiffener pillars formed of different materials. For example, a first subset of the stiffener pillars 301A are formed of a first material (e.g., Alloy 42) and a second subset of the stiffener pillars 301B are formed of a second material (e.g., Stainless Steel 430). The materials and quantities of the stiffener pillars 301A, 301B may be selected to achieve the desired coefficient of thermal expansion value of the resulting package stiffener 450.

FIG. 10E is a top-down view of a package stiffener 450, in accordance with some embodiments. This embodiment is similar to the embodiment of FIGS. 10C and 10D, except the stiffener pillars 301 include stiffener pillars formed of different materials and different geometries. For example, the first subset of the stiffener pillars 301A are formed of the first material (e.g., Alloy 42) and are cylindrical, and the second subset of the stiffener pillars 301B are formed of the second material (e.g., Stainless Steel 430) and are rectangular prisms. The materials, dimensions, and quantities of the stiffener pillars 301A, 301B may be selected to achieve the desired coefficient of thermal expansion value of the resulting package stiffener 450.

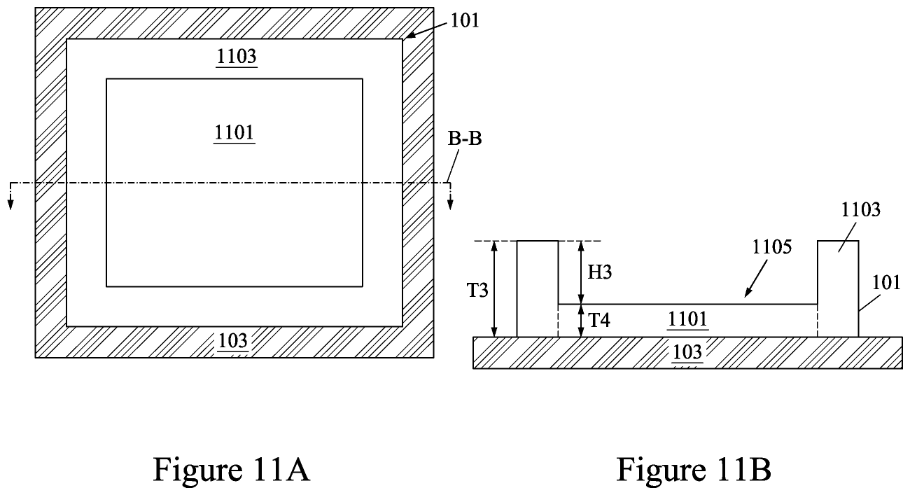

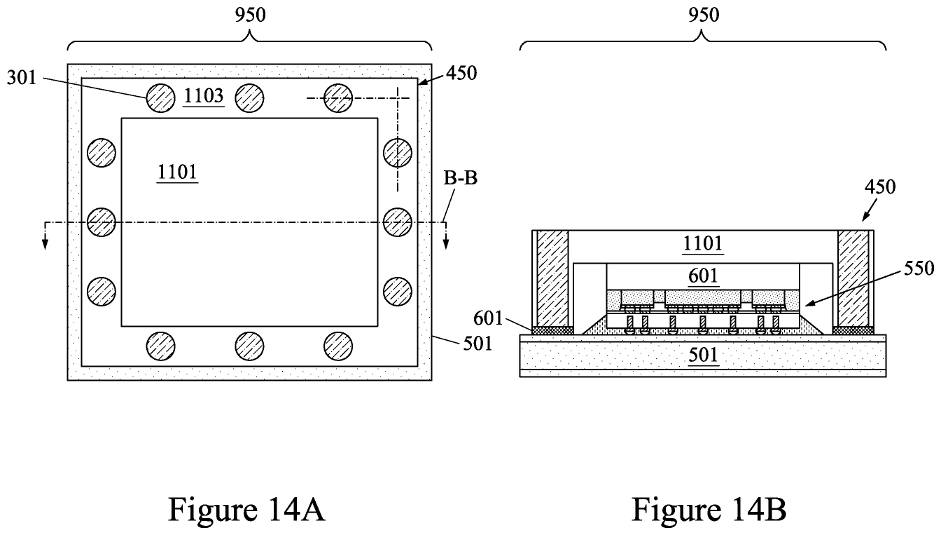

FIGS. 11A-14B are views of intermediate steps during a process for forming an integrated circuit package 950, in accordance with some embodiments. FIGS. 11A, 12A, 13A, and 14A are top-down views. FIGS. 11B, 12B, 13B, and 14B are cross-sectional views shown along cross-section B-B in, respectively, FIGS. 11A, 12A, 13A, and 14A. In some embodiments, the integrated circuit package 950 (see FIGS. 14A-14B) is a chip-on-wafer-on substrate (CoWoS) package. It should be appreciated that the integrated circuit package 950 may be another type of package.

In FIGS. 11A-11B, a stiffener main body 101 is placed on a processing substrate 103 in a similar manner as discussed above with respect to FIGS. 1A-1B. In this embodiment, the stiffener main body 101 is a metal lid having a recess 1105 extending into the middle of the metal lid. The stiffener main body 101 comprises a lid portion 1101 and ring portion 1103, which collectively define the recess 1105. The ring portion 1103 has a ring shaped profile in the top-down view, and the lid portion 1101 covers the ring portion 1103. In this embodiment, the metal lid has a U-shaped profile in the cross-sectional view. The recess 1105 has a height H3 that is large enough to provide an area for a semiconductor device to be subsequently disposed in. The height H3 may be being in the range from 0.5 mm to 2.5 mm. Further, the ring portion 1103 have a thickness T3 and the lid portion 1101 has a thickness T4, where the thickness T4 is less than the thickness T3. The thickness T3 may be in a range of 1.5 mm to 5.5 mm. The thickness T4 may be in a range of 1 mm to 3 mm. The other dimensions and material composition of the stiffener main body 101 may be similar as previously discussed with respect to FIGS. 1A-1B.

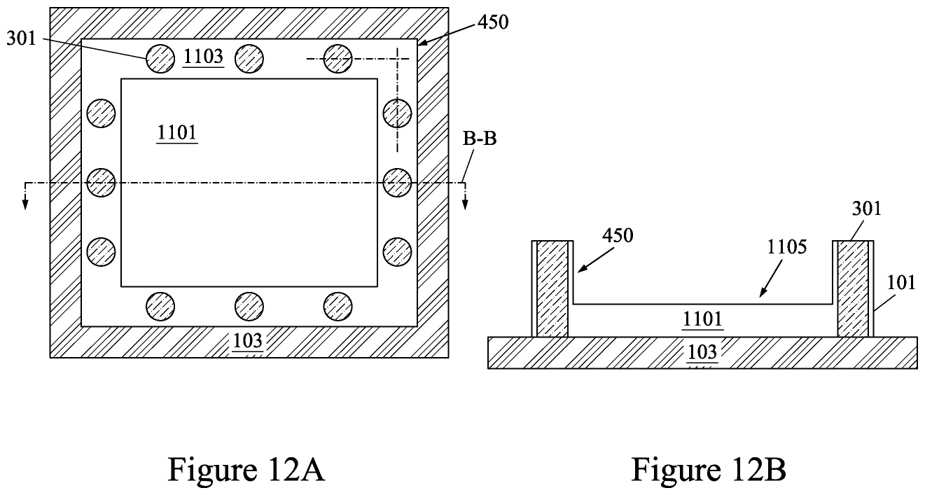

In FIGS. 12A-12B, stiffener pillars 301 are inserted into the ring portion 1103 of the stiffener main body 101, thereby forming the package stiffener 450. The stiffener pillars 301 may be inserted into the stiffener main body 101 in a similar manner as previously described, e.g., by patterning stiffener holes 201 in the stiffener main body 101, placing the stiffener pillars 301 in the stiffener holes 201, and deforming the stiffener pillars 301 so that they are secured into each of the stiffener holes 201. To facilitate subsequent processing steps in forming the integrated circuit package 950, the package stiffener 450 is then removed from the processing substrate 103 and flipped over.

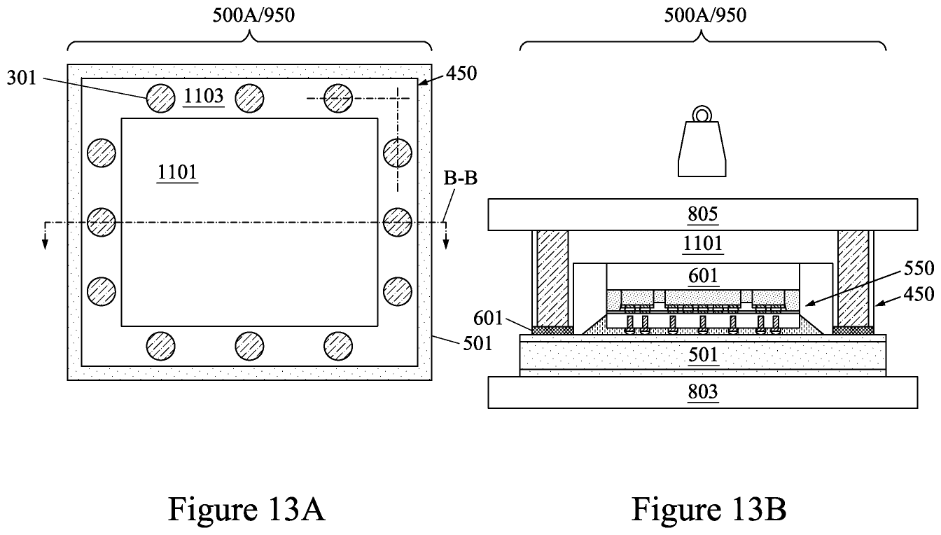

FIGS. 13A-14B show further steps in the formation of the integrated circuit package 950. The integrated circuit package 950 is completed by attaching the package stiffener 450 and a semiconductor device 550 to a package substrate 501 (see FIGS. 14A-14B). A packaging region 502A is shown, in which the integrated circuit package 950 is formed. It should be appreciated that multiple of the packaging regions 502A can be simultaneously processed, and any number of the integrated circuit packages 950 can be formed in each of the packaging regions 502A.

In FIGS. 13A-13B, a semiconductor device 550 is mounted to a package substrate 501. The semiconductor device 550 may be mounted to the package substrate 501 in a similar manner as previously described for FIGS. 5A-5B. The package stiffener 450 is then adhered to the semiconductor device 550 and the package substrate 501. The package stiffener 450 may be adhered to the semiconductor device 550 and the package substrate 501 in a similar manner as previously described for FIGS. 6A-8B, except the adhesive layer 601 is also formed on the upper surface of the semiconductor device 550. As such, the top processing plate 805 presses against the lid portion 1101 of the package stiffener 450, which additionally spreads the adhesive layer 601 across the upper surface of the semiconductor device 550.

In FIGS. 14A-14B, the integrated circuit package 950 is removed from the bottom processing plate 803 and the top processing plate 805 utilized in the attachment process (see FIG. 8B. The resulting integrated circuit package 950 is illustrated. The package stiffener 450 fully encompasses the semiconductor device 550 in the top-down view, and further comprises the lid portion 1101 covering the semiconductor device 550 in the cross-sectional view.

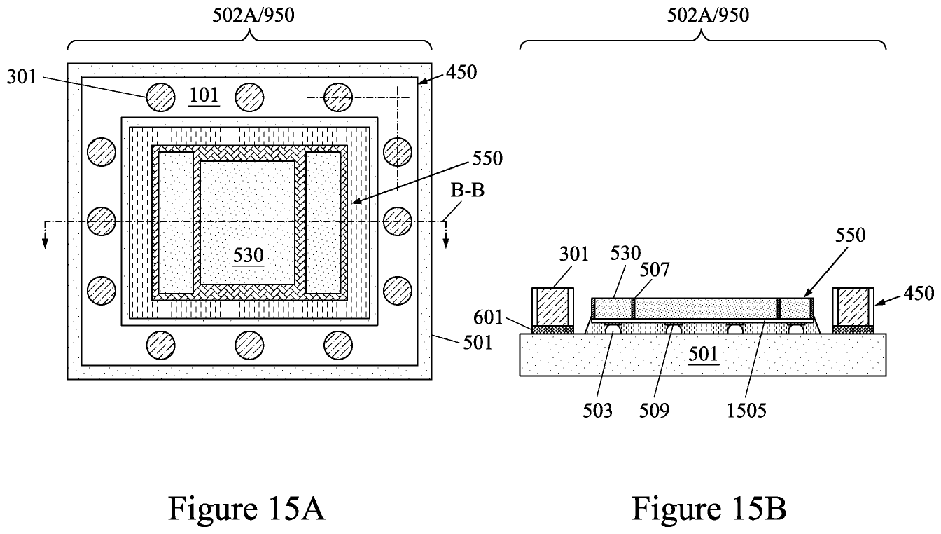

FIGS. 15A-15B are views of the integrated circuit package 950, in accordance with some embodiments. This embodiment is similar to the embodiment of FIGS. 9A-9B, except the semiconductor device 550 is an integrated fan-out (InFO) package component and the integrated circuit package 950 is an integrated fan-out on substrate (InFO-oS) package that includes one or more integrated circuit dies 530 and a redistribution structure 1505. An encapsulant 507 is formed around the integrated circuit dies 530, and the redistribution structure 1505 is built up on the encapsulant 507 and the integrated circuit dies 530. The redistribution structure 1505 includes UBMs 509. The conductive connectors 503 connect the UBMs 509 to the package substrate 501.

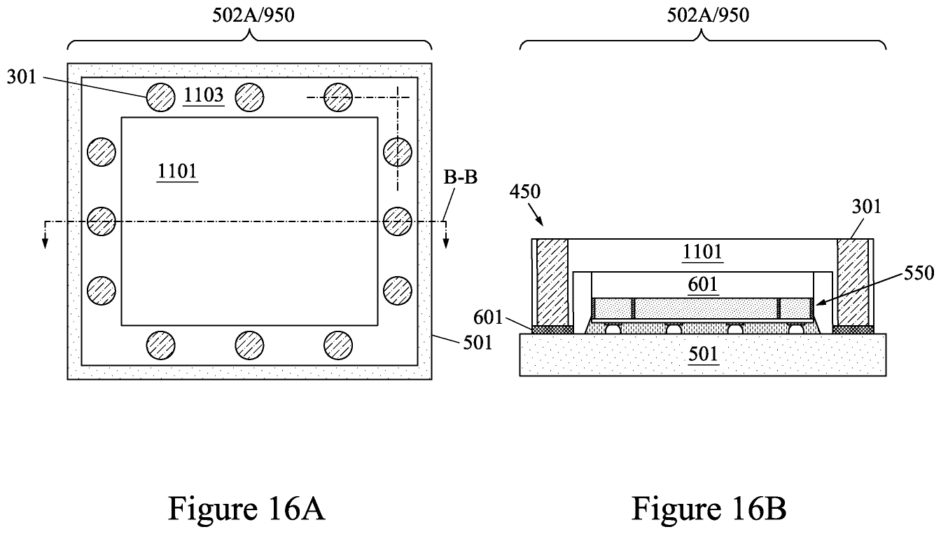

FIGS. 16A-16B are views of the integrated circuit package 950, in accordance with some embodiments. This embodiment is similar to the embodiment of FIGS. 14A-14B, except the semiconductor device 550 is an integrated fan-out (InFO) package component and the integrated circuit package 950 is an integrated fan-out on substrate (InFO-oS) package. The integrated fan-out (InFO) package component of this embodiment may be similar to that of the embodiment described for FIGS. 15A-15B.

Embodiments may achieve advantages. Incorporating the stiffener pillars 301 into the stiffener main body 101 allows for control of the equivalent coefficient of thermal expansion of the resulting package stiffener 450 such that the coefficient of thermal expansion mismatch between the package stiffener 450 and the package substrate 501 may be reduced. Reducing that coefficient of thermal expansion mismatch may improve the warpage control of the package stiffener 450 over a stiffener that does not include pillars. Further, securing the stiffener pillars 301 into the stiffener main body 101 by deforming the stiffener pillars 301 allows a close fit between the stiffener main body 101 and the stiffener pillars 301 to be achieved without using an adhesive to adhere the stiffener pillars 301 to the stiffener main body 101. Manufacturing costs may be reduced and device reliability may be improved by omission of an adhesive.

In accordance with some embodiments of the present disclosure a device includes: a package substrate; a semiconductor device attached to the package substrate; an underfill between the semiconductor device and the package substrate; and a package stiffener attached to the package substrate, the package stiffener includes: a main body extending around the semiconductor device and the underfill in a top-down view, the main body having a first coefficient of thermal expansion; and pillars in the main body, each of the pillars extending from a top surface of the main body to a bottom surface of the main body, each of the pillars physically contacting the main body, the pillars having a second coefficient of thermal expansion, the second coefficient of thermal expansion being less than the first coefficient of thermal expansion. In an embodiment the package substrate has a third coefficient of thermal expansion and the package stiffener has a fourth coefficient of thermal expansion, and wherein a first difference between the first coefficient of thermal expansion and the third coefficient of thermal expansion is greater than a second difference between the third coefficient of thermal expansion and the fourth coefficient of thermal expansion. In an embodiment the main body includes a first metal and the pillars includes a second metal, the first metal being different than the second metal. In an embodiment the main body includes a first metal, a first subset of the pillars includes a second metal, a second subset of the pillars includes a third metal, the first metal is different than the second metal, and the second metal is different than the third metal. In an embodiment the pillars are circular in the top-down view. In an embodiment the pillars are rectangular in the top-down view. In an embodiment the semiconductor device is a chip-on-wafer package component. In an embodiment the semiconductor device is an integrated fan-out package component.

In accordance with some embodiments of the present disclosure a method includes: attaching a semiconductor device to a package substrate; dispensing an underfill between the semiconductor device and the package substrate; and attaching a package stiffener to the package substrate, the package stiffener includes: a main body having a first coefficient of thermal expansion, the main body extending around the semiconductor device and the underfill in a top-down view after the semiconductor device and the package stiffener are attached to the package substrate; and pillars in the main body, each of the pillars extending through the main body, each of the pillars physically contacting the main body, the pillars having a second coefficient of thermal expansion, the second coefficient of thermal expansion being less than the first coefficient of thermal expansion. In an embodiment the package stiffener to the package substrate includes: dispensing an adhesive onto the package substrate, the adhesive forming a ring around the underfill and the semiconductor device in the top-down view; pressing the package stiffener against the adhesive; and heating the adhesive. In an embodiment the pillars and the main body of the package stiffener physically contacts the adhesive. In an embodiment further including forming the main body; patterning holes in the main body; and securing the pillars in the holes in the main body without using an adhesive. In an embodiment securing the pillars in the holes in the main body includes deforming the pillars to vertically compress and laterally expand the pillars.

In accordance with some embodiments of the present disclosure a method includes: forming a stiffener main body; patterning holes in the stiffener main body, the holes extending through the stiffener main body, the holes having a first width; placing stiffener pillars in the holes, the stiffener pillars having a larger Young's modulus than the stiffener main body, the stiffener pillars having a smaller Poisson's ratio than the stiffener main body, the stiffener pillars having a different coefficient of thermal expansion than the stiffener main body, the stiffener pillars having a second width when placed in the holes, the second width being less than the first width; and securing the stiffener pillars to the stiffener main body by deforming the stiffener pillars in the holes, the stiffener pillars having the first width after the deforming the stiffener pillars. In an embodiment forming the stiffener main body includes: forming a metal ring having an opening extending through the metal ring. In an embodiment forming the stiffener main body includes: forming a metal lid including a lid portion and a ring portion, the lid portion and the ring portion defining a recess extending into the metal lid, the holes patterned in the ring portion. In an embodiment the stiffener main body includes a first metal and the stiffener pillars includes a second metal, wherein the first metal is different than the second metal. In an embodiment the stiffener main body includes a first metal, a first subset of the stiffener pillars includes a second metal, a second subset of the stiffener pillars includes a third metal, the first metal is different than the second metal, and the second metal is different than the third metal. In an embodiment the stiffener pillars are cylindrical pillars. In an embodiment the stiffener pillars are rectangular pillars.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A device comprising:
a package substrate;
a semiconductor device attached to the package substrate;
an underfill between the semiconductor device and the package substrate; and
a package stiffener attached to the package substrate, the package stiffener comprising:
a main body extending around the semiconductor device and the underfill in a top-down view, the main body having a first coefficient of thermal expansion; and
pillars in the main body, each of the pillars extending from a top surface of the main body to a bottom surface of the main body, each of the pillars physically contacting the main body, the pillars having a second coefficient of thermal expansion, the second coefficient of thermal expansion being less than the first coefficient of thermal expansion.

2. The device of claim 1, wherein the package substrate has a third coefficient of thermal expansion and the package stiffener has a fourth coefficient of thermal expansion, and wherein a first difference between the first coefficient of thermal expansion and the third coefficient of thermal expansion is greater than a second difference between the third coefficient of thermal expansion and the fourth coefficient of thermal expansion.

3. The device of claim 1, wherein the main body comprises a first metal and the pillars comprise a second metal, the first metal being different than the second metal.

4. The device of claim 1, wherein the main body comprises a first metal, a first subset of the pillars comprise a second metal, a second subset of the pillars comprise a third metal, the first metal is different than the second metal, and the second metal is different than the third metal.

5. The device of claim 1, wherein the pillars are circular in the top-down view.

6. The device of claim 1, wherein the pillars are rectangular in the top-down view.

7. The device of claim 1, wherein the semiconductor device is a chip-on-wafer package component.

8. The device of claim 1, wherein the semiconductor device is an integrated fan-out package component.

9. A device comprising:
a semiconductor device attached to a package substrate; and
a package stiffener attached to the package substrate with an adhesive, wherein the package stiffener comprises:
a main body having a first coefficient of thermal expansion; and
embedded material structures embedded in the main body, each of the embedded material structures being continuously laterally surrounded by the main body in a plan view, the embedded material structures having a second coefficient of thermal expansion, the second coefficient of thermal expansion being less than the first coefficient of thermal expansion, wherein a first surface of the embedded material structures is level with a first surface of the main body, wherein the first surface of the embedded material structures and the first surface of the main body faces the package substrate, wherein the adhesive is a different layer than the embedded material structures.

10. The device of claim 9, further comprising:
an underfill between the semiconductor device and the package substrate.

11. The device of claim 9, wherein the main body extends continuously around the semiconductor device in the plan view.

12. The device of claim 9, wherein the main body comprises a first metal and the embedded material structures comprise a second metal, wherein the first metal is different than the second metal.

13. The device of claim 9, wherein the main body comprises a first metal, a first subset of the embedded material structures comprises a second metal, a second subset of the embedded material structures comprises a third metal, the first metal is different than the second metal, and the second metal is different than the third metal.

14. A method comprising:
forming a stiffener main body;
patterning holes in the stiffener main body, the holes extending through the stiffener main body, the holes having a first width;
placing stiffener pillars in the holes, the stiffener pillars having a larger Young's modulus than the stiffener main body, the stiffener pillars having a smaller Poisson's ratio than the stiffener main body, the stiffener pillars having a different coefficient of thermal expansion than the stiffener main body, the stiffener pillars having a second width when placed in the holes, the second width being less than the first width; and
securing the stiffener pillars to the stiffener main body by deforming the stiffener pillars in the holes, the stiffener pillars having the first width after the deforming the stiffener pillars.

15. The method of claim 14, wherein forming the stiffener main body comprises:
forming a metal ring having an opening extending through the metal ring.

16. The method of claim 14, wherein forming the stiffener main body comprises:
forming a metal lid comprising a lid portion and a ring portion, the lid portion and the ring portion defining a recess extending into the metal lid, the holes patterned in the ring portion.

17. The method of claim 14, wherein the stiffener main body comprises a first metal and the stiffener pillars comprise a second metal, wherein the first metal is different than the second metal.

18. The method of claim 14, wherein the stiffener main body comprises a first metal, a first subset of the stiffener pillars comprises a second metal, a second subset of the stiffener pillars comprises a third metal, the first metal is different than the second metal, and the second metal is different than the third metal.

19. The method of claim 14, wherein the stiffener pillars are cylindrical pillars.

20. The method of claim 14, wherein the stiffener pillars are rectangular pillars.
